(19) United States
(12) Patent Application Publication
(10) Pub. No.: US 2025/0331159 A1
(43) Pub. Date: Oct. 23, 2025

(54) SEMICONDUCTOR DEVICES, SYSTEMS, AND METHODS FOR FORMING THE SAME

(71) Applicant: Yangtze Memory Technologies Co., Ltd., Wuhan (CN)

(72) Inventor: Yuhuan ZHENG, Wuhan (CN)

(21) Appl. No.: 18/791,385

(22) Filed: Jul. 31, 2024

Related U.S. Application Data
(63) Continuation of application No. PCT/CN2024/088216, filed on Apr. 17, 2024.

(51) Int. Cl. H10B 12/00; H01L 27/06

(52) U.S. Cl. CPC H10B 12/315; H10B 12/0335; H10D 1/042; H10D 1/716; H10D 84/811

(57) ABSTRACT

Systems, devices, and methods for managing capacitor overlay in a semiconductor device are provided. In one aspect, a semiconductor device includes a transistor having a semiconductor body extending along a first direction and a gate structure adjacent to the semiconductor body. A capacitor is coupled to the transistor. The capacitor extends along the first direction and includes a first electrode, a second electrode, and a dielectric structure. An isolating spacer layer is between the transistor and the capacitor along the first direction. The first electrode includes a first portion extending between two ends of the isolating spacer layer along the first direction, and a second portion extending from the first portion along the first direction away from the transistor. A width of the first portion along a second direction perpendicular to the first direction is greater than an outer dimension of the second portion along the second direction.

### CROSS-REFERENCE TO RELATED APPLICATIONS

This application is a continuation of International Application No. PCT/CN2024/088216, filed on Apr. 17, 2024, the disclosure of which is hereby incorporated by reference in its entirety.

### TECHNICAL FIELD

The present disclosure relates to semiconductor devices and fabrication processes for semiconductor devices.

### BACKGROUND

Semiconductor memory devices may be classified into non-volatile memory devices, such as flash memory devices, and volatile memory devices, such as dynamic random-access memory (DRAM). The semiconductor memory devices can have different structures with different densities of memory cells and lines on a chip. A memory device normally includes a memory array of memory cells and control circuitries. The control circuitries can facilitate operations of the memory array.

### SUMMARY

The present disclosure describes methods, devices, systems and techniques for managing overlap between transistors and capacitors and/or between capacitors and conductive structures in three-dimensional (3D) semiconductor devices.

One aspect of the present disclosure features a semiconductor device, including a transistor having a semiconductor body extending along a first direction and a gate structure adjacent to the semiconductor body. A capacitor is coupled to the transistor along the first direction. The capacitor extends along the first direction and includes a first electrode, a second electrode, and a dielectric structure between the first electrode and the second electrode. An isolating spacer layer is between the transistor and the capacitor along the first direction. The first electrode includes a first portion extending between two ends of the isolating spacer layer along the first direction, and a second portion extending from the first portion along the first direction away from the transistor. A width of the first portion along a second direction perpendicular to the first direction is greater than an outer dimension of the second portion along the second direction.

In some implementations, the semiconductor device includes a plurality of capacitors including the capacitor. A separation distance between first portions of first electrodes of adjacent capacitors along the second direction is smaller than a separation distance between second portions of the first electrodes of the adjacent capacitors along the second direction.

In some implementations, the first portion of the first electrode of the capacitor is coupled to a first terminal of a corresponding transistor via a conductive structure.

In some implementations, the first portion of the first electrode of the capacitor has a larger area in a plane perpendicular to the first direction than an area of the conductive structure in the plane.

In some implementations, the conductive structure is within a region defined by the first portion of the first electrode of the capacitor.

In some implementations, the isolating spacer layer includes Silicon (Si), Boron (B), and Nitride (N).

In some implementations, a concentration of Boron in the isolating spacer layer is in a range from about 5% to about 70%.

In some implementations, the isolating spacer layer includes Silicon (Si), Carbon (C), and Nitride (N).

In some implementations, the capacitor includes a filling structure extending along the first direction. The first electrode is in contact with at least one surface of the filling structure.

In some implementations, the conductive structure includes at least one of metal or silicide.

In some implementations, the first portion of the first electrode of the capacitor has a larger area in a plane perpendicular to the first direction than an area of a first terminal of a corresponding transistor in the plane.

In some implementations, the second portions of the first electrodes of adjacent capacitors are separated by a separation layer along the second direction.

In some implementations, the gate structure of the transistor includes a single-side gate structure, a dual-side gate structure, a triple-side gate structure, or a gate-all-around (GAA) structure.

Another aspect of the present disclosure features a method including: forming a transistor includes a semiconductor body extending along a first direction and a gate structure adjacent to the semiconductor body; forming an isolating spacer layer; and forming a capacitor coupled to the transistor along the first direction. The capacitor extends along the first direction and includes a first electrode, a second electrode, and a dielectric structure between the first electrode and the second electrode. The first electrode includes a first portion extending between two ends of the isolating spacer layer along the first direction, and a second portion extending from the first portion along the first direction away from the transistor. A width of the first portion along a second direction perpendicular to the first direction is greater than an outer dimension of the second portion along the second direction.

In some implementations, the method includes forming a dielectric body on the isolating spacer layer; forming first openings extending through the dielectric body and the isolating spacer layer along the first direction; and partially etching the isolating spacer layer by a first etchant. The first etchant has a higher etch rate for the isolating spacer layer than for the dielectric body.

In some implementations, the first etchant includes at least one of diluted sulfuric peroxide (DSP) or Standard Clean 1 (SC1) etchant.

In some implementations, the method includes removing the dielectric body by a second etchant to form second openings. The second etchant has a lower etch rate for the isolating spacer layer than for the dielectric body.

In some implementations, forming the capacitor includes: forming, in the first openings, the first electrode; forming, in the second openings, the dielectric structure in contact with the first electrode; and forming, in the second openings, the second electrode on the dielectric structure away from the first electrode.

In some implementations, forming the first openings includes: etching the dielectric body and the isolating spacer layer by dry etching.

In some implementations, forming the isolating spacer layer includes: depositing an isolating material by plasma enhanced chemical vapor deposition (PECVD).

In some implementations, the isolating material includes Silicon (Si), Nitride (N), and Boron (B).

In some implementations, forming the isolating spacer layer includes controlling at least one of: a Boron (B) concentration, a ratio of a Silicon (Si) concentration to a Nitride (N) concentration, a plasma radio frequency (RF) power, or a deposition temperature in a deposition chamber.

In some implementations, the method includes forming a conductive structure on a first terminal of the transistor. The first portion of the first electrode of the capacitor is coupled to the first terminal of the transistor via the conductive structure.

In some implementations, the second etchant comprises hydrogen fluoride (HF).

In some implementations, at least one of a material of the first electrode or a material of the second electrode comprises titanium nitride (TiN).

In some implementations, the isolating material includes Silicon (Si), Nitride (N), and Carbon (C).

In some implementations, the deposition temperature is lower than about 600 degrees Celsius.

In some implementations, the first portion of the first electrode of the capacitor has a larger area in a plane perpendicular to the first direction than an area of the conductive structure. The conductive structure is within a region defined by the first portion of the first electrode of the capacitor.

Another aspect of the present disclosure features a system including: a memory device configured to store data and a memory controller coupled to the memory device and configured to operate the memory device. The memory device includes a transistor having a semiconductor body extending along a first direction and a gate structure adjacent to the semiconductor body. A capacitor is coupled to the transistor along the first direction. The capacitor extends along the first direction and includes a first electrode, a second electrode, and a dielectric structure between the first electrode and the second electrode. An isolating spacer layer is between the transistor and the capacitor along the first direction. The first electrode includes a first portion extending between two ends of the isolating spacer layer along the first direction, and a second portion extending from the first portion along the first direction away from the transistor. A width of the first portion along a second direction perpendicular to the first direction is greater than an outer dimension of the second portion along the second direction.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1A illustrates a cross-sectional view of an example 3D semiconductor device.

FIG. 1B is an enlarged view of a region of FIG. 1A.

FIG. 1C illustrates a top view showing overlapping between example conductive structures and example first portions of first electrodes of capacitors.

FIG. 1D illustrate a cross-section view of another implementation of capacitors of the semiconductor device of FIG. 1A.

FIGS. 2A-2E illustrate cross-section views of an example semiconductor device at various stages of a fabrication process.

FIGS. 3A-3C illustrate example graphs of etch rate with respect to deposition temperature and Boron concentration.

FIG. 4 is a flow diagram of an example process for forming an example semiconductor device.

FIG. 5 illustrates a block diagram of a system.

It is to be understood that the various exemplary implementations shown in the figures are merely illustrative representations and are not necessarily drawn to scale.

### DETAILED DESCRIPTION

In DRAM (Dynamic Random Access Memory) technology, a capacitor and a transistor can form a DRAM cell. The capacitor stores an electrical charge representing a data bit, while the transistor acts as a switch, controlling a flow of charge to read or write data to the DRAM cell. The overlay between the capacitor and transistor is crucial, as a misalignment or deviation in overlay can lead to various issues, such as increased resistance, or a reduction in the effectiveness of charge storage and retrieval. Therefore, control of the overlay between the capacitor and transistor is essential in DRAM manufacturing.

Implementations of the present disclosure provide semiconductor devices and methods for forming such semiconductor devices. In some implementations, a semiconductor device includes a transistor having a semiconductor body extending along a first direction and a gate structure adjacent to the semiconductor body. A capacitor is coupled to the transistor along the first direction. The capacitor extends along the first direction and includes a first electrode, a second electrode, and a dielectric structure between the first electrode and the second electrode. An isolating spacer layer is between the transistor and the capacitor along the first direction. The first electrode includes a first portion extending between two ends of the isolating spacer layer along the first direction, and a second portion extending from the first portion along the first direction away from the transistor. A width of the first portion along a second direction perpendicular to the first direction is greater than an outer dimension of the second portion along the second direction.

Implementations of the present disclosure can provide one or more of the following technical advantages and/or benefits. For example, an isolating spacer layer can be formed between capacitors and transistors in DRAM cells using plasma enhanced chemical vapor deposition (PECVD) at a lower deposition temperature compared to thermal CVD. This isolating spacer layer can have a higher etch rate when exposed to a wet etchant (e.g., diluted sulfuric peroxide (DSP) or Standard Clean 1 (SC1) etchant). Higher etch rate can form larger capacitor openings in the isolating spacer layer, which, in turn, define a larger dimension of a first portion of a first electrode of the capacitor. The larger dimension of the first electrode of the capacitor can enhance alignment between the capacitors and transistors and provide a wider process window. This alignment enhancement is particularly advantageous when adjacent transistors along the bit line direction have unequal spacing distances, while adjacent capacitors along the same direction have equal spacing distances. Better alignment can offer several benefits, such as improved manufacturing yield, increased device performance and enhanced reliability. In addition, implementations of the present disclosure does not require additional process steps to form a larger first portion of the first electrode of the capacitor. The etch rate can be controlled by adjusting deposition parameters, such as deposition temperature, and a concentration of Boron (or one or more other dopants) of the isolating spacer layer. Therefore, the techniques described herein can enhance alignment between transistors and capacitors for memory cells without compromising manufacturing cost.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

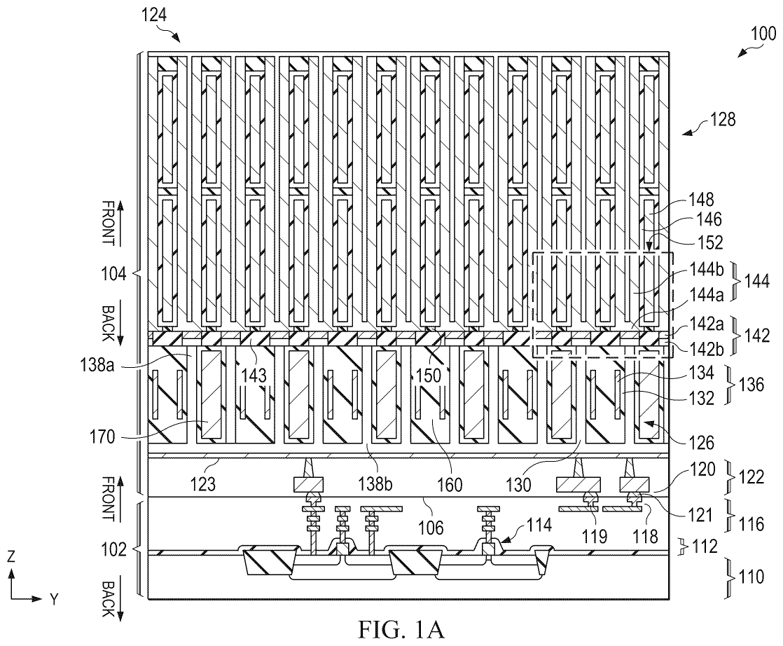

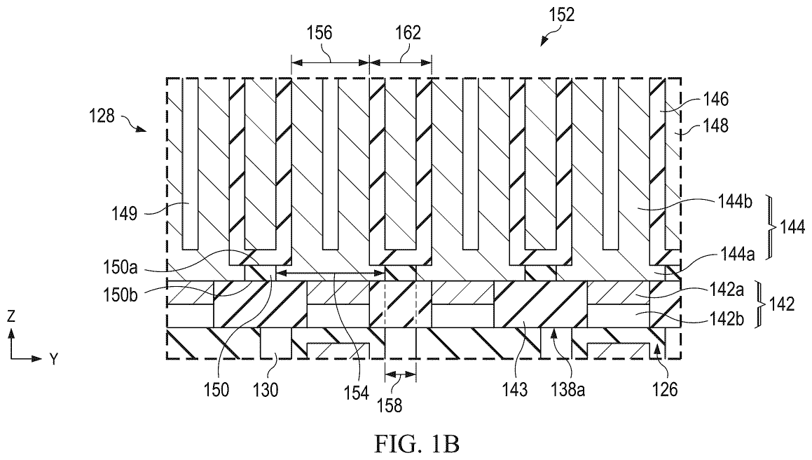

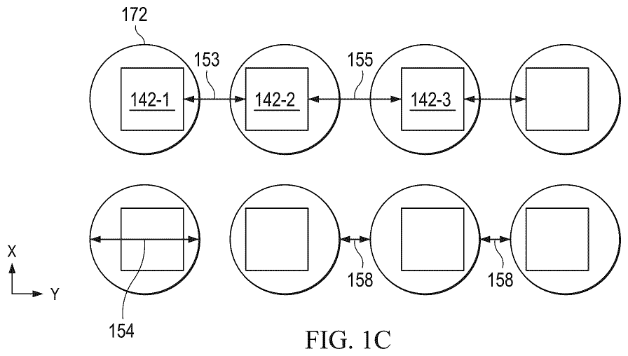

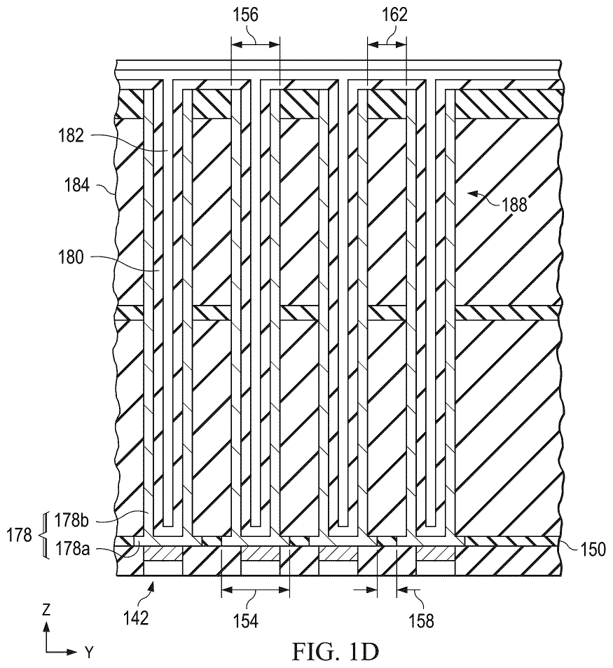

FIG. 1A illustrates a side view of a cross-section of an example 3D semiconductor device 100. The 3D semiconductor device 100 can be a 3D dynamic random-access memory (DRAM). It is understood that FIG. 1A is for illustrative purposes only and may not necessarily reflect the actual device structure (e.g., interconnections) in practice. In some implementations, the 3D semiconductor device 100 is a bonded chip including a first semiconductor structure 102 and a second semiconductor structure 104 stacked over the first semiconductor structure 102. The first and second semiconductor structures 102 and 104 can be jointed at bonding interface 106 therebetween.

As shown in FIG. 1A, the first semiconductor structure 102 can include a substrate 110, which can include silicon (e.g., single crystalline silicon, c-Si), SiGe, GaAs, Ge, SOI, or any other suitable materials. The first semiconductor structure 102 can include peripheral circuits 112 on and/or in the substrate 110. In some implementations, the peripheral circuits 112 include a plurality of transistors 114 (e.g., planar transistors and/or 3D transistors). Trench isolations (e.g., shallow trench isolations (STIs)) and doped regions (e.g., wells, sources, and drains of transistors 114) can be formed on or in the substrate 110 as well. In some examples, the peripheral circuits 112 are formed using complementary metal-oxide-semiconductor (CMOS) technology, and the first semiconductor structure 102 can be also formed on a semiconductor die that can be referred to as a control die or a CMOS die 102.

In some implementations, the first semiconductor structure 102 further includes an interconnect layer 116 above the peripheral circuits 112 to transfer electrical signals to and from the peripheral circuits 112. The interconnect layer 116 can include a plurality of interconnects (also referred to herein as “contacts”), including lateral interconnect lines and VIA contacts. The interconnect layer 116 can further include one or more interlay dielectric (ILD) layers in which the interconnect lines and via contacts can form. That is, the interconnect layer 116 can include interconnect lines and via contacts in multiple ILD layers. In some implementations, peripheral circuits 112 are coupled to one another through the interconnects in the interconnect layer 116. The interconnects in interconnect layer 116 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As shown in FIG. 1A, the first semiconductor structure 102 has a front side and a back side, and the first semiconductor structure 102 can further include a bonding layer 118 at the back side at the bonding interface 106 and above the interconnect layer 116 and the peripheral circuits 112. The bonding layer 118 can include a plurality of bonding contacts 119 and dielectrics electrically isolating the bonding contacts 119. The bonding contacts 119 can include conductive materials, such as Cu. The remaining area of the bonding layer 118 can be formed with dielectric materials, such as silicon oxide. The bonding contacts 119 and surrounding dielectrics in the bonding layer 118 can be used for hybrid bonding. Similarly, as shown in FIG. 1A, the second semiconductor structure 104 can also include a bonding layer 120 at the bonding interface 106 and above the bonding layer 118 of the first semiconductor structure 102. The bonding layer 120 can include a plurality of bonding contacts 121 and dielectrics electrically isolating the bonding contacts 121. The bonding contacts 121 can include conductive materials, such as Cu. The remaining area of the bonding layer 120 can be formed with dielectric materials, such as silicon oxide. The bonding contacts 121 and surrounding dielectrics in the bonding layer 120 can be used for hybrid bonding. The bonding contacts 121 can be in contact with the bonding contacts 119 at the bonding interface 106. In some implementations, the bonding layer 120 includes a dielectric layer opposing memory cells (e.g., DRAM cells) 124 with a bit line 123 positioned between the dielectric layer and the memory cells 124, as shown in FIG. 1A. The dielectric layer can include the bonding interface 106 having the bonding contacts 121.

The second semiconductor structure 104 can be bonded on top of the first semiconductor structure 102 in a face-to-face manner at the bonding interface 106. In some implementations, the bonding interface 106 is disposed between the bonding layers 120 and 118 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, the bonding interface 106 is the place at which bonding layers 120 and 118 are met and bonded. In some examples, the bonding interface 106 can be a layer with a certain thickness that includes the top surface of the bonding layer 118 of the first semiconductor structure 102 and the bottom surface of the bonding layer 120 of the second semiconductor structure 104.

In some implementations, the second semiconductor structure 104 further includes an interconnect layer 122 including bit lines 123 above the bonding layer 120 to transfer electrical signals. The interconnect layer 122 can include a plurality of interconnects, such as mid end of line (MEOL) interconnects and back end of line (BEOL) interconnects. In some implementations, the interconnects in interconnect layer 122 also include local interconnects, such as the bit lines 123 and word line contacts (not shown). The interconnect layer 122 can further include one or more ILD layers in which the interconnect lines and via contacts can form. The interconnects in the interconnect layer 122 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

In some implementations, the peripheral circuits 112 include a word line driver/row decoder coupled to the word line contacts in the interconnect layer 122 through the bonding contacts 121 and 119 in the bonding layers 120 and 118 and the interconnect layer 116. In some implementations, the peripheral circuits 112 include a bit line driver/column decoder coupled to the bit lines 123 and bit line contacts in the interconnect layer 122 through the bonding contacts 121 and 119 in the bonding layers 120 and 118 and the interconnect layer 116. In some implementations, the bit line 123 is a metal bit line, as opposed to semiconductor bit lines (e.g., doped silicon bit lines). For example, the bit line 123 may include W, Co, Cu, Al, or any other suitable metals having higher conductivities than doped silicon. In some implementations, the bit line contact is an ohmic contact as opposed to a Schottky contact.

In some implementations, the bit line 123 is made of a composite conductive material that can be based on a metallic material (e.g., W, Co, Cu, Al) and a semiconductor material (e.g., Si). For example, the composite conductive material can include metal silicide, e.g., such as WSi, CoSi, CuSi, AlSi, or any other suitable metal silicides having higher conductivities than doped silicon.

In some implementations, the second semiconductor structure 104 includes a DRAM device in which memory cells 124 are provided in the form of an array of DRAM cells 124 above the interconnect layer 122 and the bonding layer 120. That is, the interconnect layer 122 including the bit lines 123 can be disposed between bonding layer 120 and array of DRAM cells 124. A bit line 123 in the interconnect layer 122 can be coupled to a string of DRAM cells 124. In some implementations, the second semiconductor structure 104 is formed on a semiconductor die and can be referred to as array die 104.

In some implementations, a semiconductor device can include multiple array dies (e.g., the array die 104) and a CMOS die (e.g., the CMOS die 102). The multiple array dies and the CMOS die can be stacked and bonded together. The CMOS die can be respectively coupled to each of the multiple array dies, and can respectively drive each of the multiple array dies to operate in the similar manner as the semiconductor device. The semiconductor device can be any suitable device. In some examples, the semiconductor device includes at least a first wafer and a second wafer bonded face to face. The array die can be disposed with other array dies on the first wafer, and the CMOS die can be disposed with other CMOS dies on the second wafer. The first wafer and the second wafer can be bonded together, thus the array dies on the first wafer can be bonded with corresponding CMOS dies on the second wafer. In some examples, the semiconductor device is a chip with at least the array die and the CMOS die bonded together. In an example, the chip is diced from wafers that are bonded together. In another example, the semiconductor device is a semiconductor package that includes one or more semiconductor chips assembled on a package substrate.

Each DRAM cell 124 can include a vertical transistor 126 and a capacitor 128 coupled to the vertical transistor 126. DRAM cell 124 can be a 1T1C cell consisting of one transistor and one capacitor. It is understood that DRAM cell 124 may be of any suitable configurations, such as 2T1C cell, 3T1C cell, etc. The vertical transistor 126 can be a MOSFET used to switch a respective DRAM cell 124. In some implementations, the vertical transistor 126 includes a semiconductor body 130 (the active region in which a channel can form) extending vertically (in the z-direction), and a gate structure 136 in contact with one side of semiconductor body 130. In a single-gate vertical transistor, the semiconductor body 130 can have a cuboid shape or a cylinder shape, and the gate structure 136 can abut a single side of semiconductor body 130 in a plane view, e.g., as shown in FIG. 1A. In some implementations, the vertical transistor 126 has a structure including two or more gates, e.g., a two-gates structure, a three-gates structure, or a gate all around (GAA) structure. In some implementations, the gate structure 136 includes a gate electrode 134 and a gate dielectric 132 laterally between the gate electrode 134 and the semiconductor body 130 in a bit line direction (e.g., in the Y direction). In some implementations, the gate dielectric 132 abuts one side of the semiconductor body 130, and the gate electrode 134 abuts the gate dielectric 132.

As shown in FIG. 1A, the semiconductor body 130 has two ends (the upper end and lower end in FIG. 1A) in the vertical direction (the z-direction). In some implementations, at least one end (e.g., the lower end) extends beyond (not shown) gate dielectric 132 in the vertical direction (the z-direction) into the ILD layers. In some implementations, one end (e.g., the upper end) of the semiconductor body 130 is flush with the respective end (e.g., the upper end) of the gate dielectric 132. In some implementations, both ends (the upper end and lower end) of the semiconductor body 130 extend beyond the gate electrode 134, respectively, in the vertical direction (the z-direction) into ILD layers. That is, the semiconductor body 130 can have a larger vertical dimension (e.g., the depth) than that of the gate electrode 134 (e.g., in the z-direction), and neither the upper end nor the lower end of semiconductor body 130 is flush with the respective end of the gate electrode 134. Thus, short circuits between the bit lines 123 and the word lines/gate electrodes 134 or between the word lines/gate electrodes 134 and the capacitors 128 can be avoided. The vertical transistor 126 can further include a first terminal 138a and a second terminal 138b disposed at the two ends (the upper end and lower end) of the semiconductor body 130, respectively, in the vertical direction (the z-direction). One of the first terminal 138a and the second terminal 138b is a source terminal, and the other one of the first terminal 138a and the second terminal 138b is a drain terminal. In some implementations, the first terminal 138a (e.g., at the upper end in FIG. 1A) is coupled to the capacitor 128, and the second terminal 138b (e.g., at the lower end in FIG. 1A) is coupled to the bit line 123. That is, the vertical transistor 126 can have a first terminal in the positive z-direction and a second terminal opposite the first terminal in the negative z-direction, as shown in FIG. 1A.

In some implementations, the semiconductor body 130 includes semiconductor materials, such as single crystalline silicon, polysilicon, amorphous silicon, Ge, any other semiconductor materials, or any combinations thereof. In one example, semiconductor body 130 may include single crystalline silicon. The first and second terminals 138a, 138b can be doped with N+ type dopants (e.g., Phosphorus (P) or Arsenic (As)) or P-type dopants (e.g., Boron (B) or Gallium (Ga)) at a desired doping level. In some implementations, a silicide layer, such as a metal silicide layer, is formed between the second terminal 138b of the vertical transistor 126 and the bit line 123 as the bit line contact or between the first terminal 138a of the vertical transistor 126 and the first electrode of the capacitor 128 as capacitor contact 142 to reduce the contact resistance. The capacitor contact 142 can also be referred to as the conductive structure 142 in this disclosure.

In some implementations, gate dielectric 132 includes dielectric materials, such as silicon oxide, silicon nitride, or high-k dielectrics including, but not limited to, Al2O3, HfO2, Ta2O5, ZrO2, TiO2, or any combination thereof. In some implementations, gate electrode 134 includes a conductive material including, but not limited to W, Co, Cu, Al, TiN, TaN, polysilicon, silicide, or any combination thereof. In some implementations, the gate electrode 134 includes multiple conductive layers, such as a W layer over a TiN layer. In one example, the gate structure 136 may be a “gate oxide/gate poly” gate in which the gate dielectric 132 includes silicon oxide and gate electrode 134 includes doped polysilicon. In another example, gate structure 136 may be an HKMG in which gate dielectric 132 includes a high-k dielectric and gate electrode 134 includes a metal.

As described above, since the gate electrode 134 may be part of a word line or extend in the word line direction (e.g., the X direction) as a word line, the second semiconductor structure 104 of the 3D semiconductor device 100 can also include a plurality of word lines each extending in the word line direction. Each word line 134 can be coupled to a row of DRAM cells 124. That is, the bit line 123 and the word line 134 can extend in two perpendicular lateral directions, and the semiconductor body 130 of the vertical transistor 126 can extend in the vertical direction perpendicular to the two lateral directions in which the bit line 123 and the word line 134 extend. Word lines 134 are in contact with word line contacts (not shown). In some implementations, the word lines 134 include conductive materials including, but not limited to W, Co, Cu, Al, TiN, TaN, polysilicon, silicides, or any combination thereof. In some implementations, the word line 134 includes multiple conductive layers, such as a W layer over a TiN layer, as shown in FIG. 1A.

In some implementations, as shown in FIG. 1A, the vertical transistor 126 extends vertically through and contacts the word lines 134, and the second terminal 138b of vertical transistor 126 at the lower end thereof is in contact with the bit line 123 (or bit line contact if any). Accordingly, the word lines 134 and the bit lines 123 can be disposed in different planes in the vertical direction due to the vertical arrangement of vertical transistor 126, which simplifies the routing of the word lines 134 and the bit lines 123. In some implementations, the bit lines 123 are disposed vertically between the bonding layer 120 and the word lines 134, and the word lines 134 are disposed vertically between the bit lines 123 and the capacitors 128. The word lines 134 can be coupled to the peripheral circuits 112 in the first semiconductor structure 102 through word line contacts (not shown) in the interconnect layer 122, the bonding contacts 121 and 119 in the bonding layers 120 and 118, and the interconnects in the interconnect layer 116. Similarly, the bit lines 123 in the interconnect layer 122 can be coupled to the peripheral circuits 112 in the first semiconductor structure 102 through the bonding contacts 121 and 119 in the bonding layers 120 and 118 and the interconnects in the interconnect layer 116.

In some implementations, the vertical transistors 126 can be arranged in a mirror-symmetric manner to increase the density of DRAM cells 124 in the bit line direction (the Y direction). As shown in FIG. 1A, two adjacent vertical transistors 126 in the bit line direction are mirror-symmetric to one another with respect to a trench isolation 160. That is, the second semiconductor structure 104 can include a plurality of trench isolations 160 each extending in the word line direction (the X direction) in parallel with word lines 134 and disposed between vertical gates 134 of two adjacent rows of the vertical transistors 126. In some implementations, the rows of vertical transistors 126 separated by the trench isolation 160 are mirror-symmetric to one another with respect to the trench isolation 160. The trench isolation 160 can be formed with dielectric materials including, but not limited to, silicon oxide, silicon nitride, silicon oxynitride, low-k dielectrics, or any combination thereof. It is understood that the trench isolation 160 may include an air gap each disposed laterally between adjacent vertical gates 134. Air gaps may be formed due to the relatively small pitches of vertical transistors 126 in the bit line direction (e.g., the Y direction). On the other hand, the relatively small dielectric constant of air in air gaps (e.g., about ¼ of the dielectric constant of silicon oxide) can improve the insulation effect between vertical transistors 126 (and rows of DRAM cells 124) compared with some dielectrics (e.g., silicon oxide). Similarly, in some implementations, air gaps are formed laterally between word lines/gate electrodes 134 in the bit line direction as well, depending on the pitches of word lines/gate electrodes 134 in the bit line direction.

In some implementations, instead of the trench isolation 160 having the air gap being disposed between adjacent vertical gates 134 of two adjacent rows of the vertical transistors 126, a shielding conductive structure 170 (e.g., including metal such as W) is disposed between adjacent semiconductor bodies 130 of two adjacent rows of vertical transistors 126. The shielding conductive structure 170 can be in contact with at least one of the adjacent semiconductor bodies 130 and can be coupled to a low voltage (e.g., a fixed negative voltage), which can reduce charge build-up in the memory cells 124, thereby mitigating the floating body effect in the memory cells 124. Moreover, by applying a fixed low voltage on the shielding conductive structure 170 between the memory cells 124, a threshold voltage of the memory cells 124 can be conveniently adjusted, which can reduce the overall manufacturing complexity and cost, and improve reliability of the memory cells 124. Further, the conductive structure 170 can be coupled out from a same side as word lines or a different side from the word lines. For example, the shielding conductive structure 170 can be coupled out from the back side of the second semiconductor structure 104. The shielding conductive structure 170 can be also referred as shielding conductive material. The trench isolation having such shielding conductive structure 170 may be also referred to as trench isolation (TISO) in this disclosure.

As shown in FIG. 1A, in some implementations, a capacitor 128 includes a first electrode 144 above and coupled to the first terminal 138a of vertical transistor 126, e.g., the upper end of the semiconductor body 130, via a capacitor contact 142. The capacitor contact 142 can also be referred to as conductive structure 142 in this disclosure. Adjacent capacitor contacts 142 (or adjacent conductive structures 142) can be isolated by a dielectric layer 143. The dielectric layer 143 can include silicon oxide or silicon nitride. In some implementations, the first electrode 144 includes two portions, a first portion 144a and a second portion 144b. Adjacent first portions 144a of the first electrodes 144 can be separated by an isolating spacer layer 150, as described with further details below in FIG. 1B. The second portion 144be of the first electrode 144 extends from the first portion 144a along Z direction away from the transistors 126. In some implementations, the first portions 144a of the first electrode 144 of a capacitor 128 is coupled to the capacitor contact 142. In some implementations, the capacitor contact 142 is an ohmic contact, such as a metal silicide contact, as opposed to a Schottky contact. In some implementations, the capacitor contact 142 includes a first layer 142a in contact with the first electrode 144 of the vertical transistor 126 and a second layer 142b in contact with the first terminal 138a of the capacitor 128. In some examples, the first layer 142a includes a metallic silicide material, and the second layer 142b includes doped polysilicon. In some implementation, at least part of the capacitor contact 142 is used as the first terminal 138a of the capacitor 128.

The capacitor 128 can also include a capacitor dielectric 146 in contact with the first electrode 144, and a second electrode 148 in contact with the capacitor dielectric 146. That is, the capacitor dielectric 146 can be sandwiched between the electrodes. The capacitor dielectric 146 can also be referred to as the dielectric structure 146 in this disclosure. In some implementations, each first electrode 144 is coupled to a first terminal 138a of a respective vertical transistor 126 in a same DRAM cell, while all second electrodes 148 are coupled to a common plate coupled to the ground, e.g., a common ground. The capacitor 128 can have a first end in the negative z-direction and a second end opposite the first end in the positive z-direction, as shown in FIG. 1A. In some implementations, the first end of the capacitor 128 is coupled to the first terminal 138a of the vertical transistor 126 via an ohmic contact (e.g., the capacitor contact 142 made of a metal silicide material).

It is understood that the structure and configuration of a capacitor 128 are not limited to the example in FIG. 1A and may include any suitable structure and configuration, such as a cup capacitor (e.g., as illustrated in FIG. 1D), a planar capacitor, a stack capacitor, a multi-fins capacitor, a cylinder capacitor, a trench capacitor, or a substrate-plate capacitor. In some implementations, the capacitor dielectric 146 includes dielectric materials, such as silicon oxide, silicon nitride, or high-k dielectrics including, but not limited to, Al2O3, HfO2, Ta2O5, ZrO2, TiO2, or any combination thereof. It is understood that in some examples, a capacitor 128 may be a ferroelectric capacitor used in a FRAM cell, and the capacitor dielectric 146 may be replaced by a ferroelectric layer having ferroelectric materials, such as PZT or SBT. In some implementations, the electrodes include conductive materials including, but not limited to W, Co, Cu, Al, TiN, TaN, polysilicon, silicides, or any combination thereof.

As shown in FIG. 1A, vertical transistor 126 extends vertically through and contacts the word lines 134, the second terminal 138b of vertical transistor 126 at the lower end thereof is in contact with the bit line 123, and the first terminal 138a of vertical transistor 126 at the upper end thereof is coupled to the capacitor 128. That is, the bit line 123 and the capacitor 128 can be disposed in different planes in the vertical direction and coupled to opposite ends of vertical transistor 126 of DRAM cell 124 in the vertical direction due to the vertical arrangement of vertical transistor 126. In some implementations, the bit line 123 and the capacitor 128 are disposed on opposite sides of the vertical transistor 126 in the vertical direction, which simplifies the routing of the bit lines 123 and reduces the coupling capacitance between the bit lines 123 and the capacitors 128 compared with DRAM cells in which the bit lines and capacitors are disposed on the same side of the planar transistors.

As shown in FIG. 1A, in some implementations, the vertical transistors 126 are disposed vertically between the capacitors 128 and the bonding interface 106. That is, the vertical transistors 126 can be arranged closer to the peripheral circuits 112 of the first semiconductor structure 102 and the bonding interface 106 than the capacitors 128. Since the bit lines 123 and the capacitors 128 are coupled to opposite ends of the vertical transistors 126, the bit lines 123 (as part of the interconnect layer 122) are disposed vertically between the vertical transistors 126 and the bonding interface 106. As a result, the interconnect layer 122 including bit lines 123 can be arranged close to the bonding interface 106 to reduce the interconnect routing distance and complexity.

Although not shown, it is to be understood that more than one array of DRAM cells 124 may be stacked over one another to vertically scale up the number of DRAM cells 124.

In some implementations, a second semiconductor structure 104 includes a substrate disposed below the DRAM cells 124. The DRAM cells 124 can be formed in a front side of the substrate, and the bit lines 123 can be formed in a back side of the substrate. The bit lines 123 can be conductively coupled to the DRAM cells 124 (e.g., the terminals 138a, 138b of the vertical transistors 126) through the substrate.

FIG. 1B is an enlarged view of the region 152 (enclosed by the dashed line in FIG. 1A). As noted above, the capacitor 128 can include the first electrode 144, the second electrode 148 and the dielectric structure 146 between the first electrode 144 and the second electrode 148. In some implementations, the capacitor 128 includes a filling structure 149 extending along the Z direction, and the first electrode 144 is in contact with at least one surface of the filling structure 149. In some implementations, the filling structure 149 is made of a dielectric material including, but not limited to, polysilicon, silicon carbide, carbon, or any combination thereof.

In some implementations, the first electrode 144 of the capacitor 128 is coupled to the first terminal 138a of the transistor 126 through the conductive structure 142. The conductive structure 142 can include at least one of metal or silicide, including without limitation to, W, Co, Cu, Al, NiSi, WSi, CoSi, CuSi, AlSi, or any other suitable metal silicides having higher conductivities than doped silicon. In some implementations, the conducive structure 142 includes two layers. The first layer 142a can include a silicide material and the second layer 142b can include doped polysilicon.

An isolating spacer layer 150 is positioned between the transistor 126 and the capacitor 128, or between the dielectric layer 143 and the capacitor dielectric structure 146 of the capacitor 128 along the first direction, e.g., Z-direction. The isolating spacer layer 150 can be made of a dielectric material. In some implementations, an isolating spacer includes Silicon (Si), Boron (B), and Nitride (N). In some implementations, a concentration of Boron in the isolating spacer is in a range from about 5% to about 70%. In some implementations, the isolating spacer includes Silicon (Si), Carbon (C), and Nitride (N). In some implementations, the isolating spacer includes Silicon (Si), Boron (B), Carbon (C), and Nitride (N).

As shown in FIG. 1B, the first electrode 144 can include a first portion 144a and a second portion 144b. The first portion 144a can extend between two ends of the isolating spacer layer 150 along the first direction, e.g., the Z direction. For example, the isolating spacer layer 150 can include a first end 150a and a second end 150b opposite to the first end 150a along Z direction. The distance between the first end 150a and the second end 150b along Z direction can define a thickness of the isolating spacer layer 150. The first portion 144a of the first electrode 144 can extend through the isolating spacer layer 150 between these two ends, e.g., along its thickness direction. The second portion 144b of the first electrode 144 can extend from the first portion 144a along the first direction away from the transistor 126, e.g., along the positive Z direction. In some implementations, the first portion 144a of the first electrode 144 of the capacitor 128 is coupled to a first terminal 138a of a corresponding transistor 126 via the conductive structure 142. In some implementations, the filling structure 149 is surrounded by the second portion 144b of the first electrode 144 of the capacitor 128. In some implementations, the second portion 144b of the first electrode 144 of the capacitor 128 has a hollow cylinder shape.

In some implementations, the width 154 of the first portion 144a along a second direction, e.g., the bit line direction or Y direction, is greater than an outer dimension 156 of the second portion 144b along the second direction. In some implementations, the first portion 144a of the first electrode 144 has a circular shape in X-Y plane view (e.g., as illustrated in FIG. 1C). The width 154 of the first portion 144a of the first electrode 144 can be its diameter. Likewise, the second portion 144b of the first electrode 144 can also have a circular shape in X-Y plane view. The outer dimension 156 of the second portion 144b can be its outer diameter. In some implementations, the outer dimension 156 of the second portion 144b is the distance between adjacent dielectric structures 146 along Y direction.

In some implementations, a separation distance 158 between first portions 144a of first electrodes 144 of adjacent capacitors 128 along Y direction is smaller than a separation distance 162 between second portions 144b of the first electrodes 144 of the adjacent capacitors 128 along the same direction. In some implementations, the separation distance 158 between adjacent first portions 144a is equal to the width of the isolating spacer layer 150 between the adjacent first portions 144a along Y direction, as illustrated in FIG. 1C.

FIG. 1C illustrates a top view showing overlapping between the conductive structures 142 and the first portion 144a of the first electrode 144 of the capacitor 128. As illustrated, in some implementations, the first portion 144a of the first electrode 144 of the capacitor 128 can have a circular shape in the top view. The area of the first portion 144a of the first electrode 144 of the capacitor 128 can be defined by the region 172 (enclosed by solid line). In some implementations, the conductive structures 142 have a rectangle shape or a square shape. It is to be understood that the conductive structures 142 can have a circular shape, an elliptic shape, or any other suitable shape, while the first portion 144a of the first electrode 144 of the capacitor 128 can have a rectangle shape or a square shape or any other suitable shape.

In some implementations, the first portion 144a of the first electrode 144 of the capacitor 128 has a larger area in a plane (e.g., X-Y plane) perpendicular to the first direction (e.g., Z direction) than an area of the conductive structure 142 in the plane, as illustrated in FIG. 1C. In some implementations, the conductive structure 142 is within a region 172 defined by the first portion 144a of the first electrode 144 of the capacitor 128. In some implementations, the first portion 144a of the first electrode 144 of the capacitor 128 has a larger area in the X-Y plane than an area of a first terminal 138a of a corresponding transistor 126 in the plane (e.g., as illustrated in FIG. 1B).

In some implementations, adjacent transistors 126 or adjacent conductive structures 142 along the bit line direction (e.g., Y direction) have unequal spacing distances, while adjacent capacitors 128 along the same direction have equal spacing distances. For example, as illustrated in FIG. 1C, the spacing distance 153 between a first conductive structure 142-1 and a second conductive structure 142-2 is not equal to the spacing distance 155 between the second conductive structure 142-2 and a third conductive structure 142-3. In contrast, the separation distance 158 between two neighboring first portions 144a of the first electrodes 144 are identical or substantially similar. In configurations like this, achieving alignment between the capacitor 128 and the first conducive structures 142-1 (or transistors 126) can be challenging. To address this issue, as noted above, the width (e.g., the diameter) of the first portion 144a of the first electrode 144 can be made greater than the outer dimeter of the second portion 144b of the first electrode 144. This enlarged region 172 of the first portion 144a provides a wider alignment margin between the capacitor 128 and the conductive structure 142 and increases process windows. Better alignment can offer several benefits, such as reduced contact resistance, improved manufacturing yield, increased device performance and enhanced reliability.

It is to be understood that the structure and configuration of the capacitors in the semiconductor device 100 are not limited to the example in FIGS. 1A-1B and may include any suitable structure and configuration, e.g., a cup capacitor. FIG. 1D illustrate a cross-section view of an example cup capacitor 188. The cup capacitor 188 can be implemented as the capacitor 128 in FIG. 1A.

As illustrated, the cup capacitor 188 includes a first electrode 178, a second electrode 182 and a dielectric structure 180 between the first electrode 178 and the second electrode 182. The second electrode 182 of the cup capacitor 188 can have a “T” shape, where a first part of “T” shape extends vertically along Z axis inside the dielectric structure 180, and a second part of “T” shape extends laterally along Y axis (e.g., BL direction). In some implementations, the first electrode 178 and the second electrode 182 include a conductive material including, but not limited to, SiGe, W, Co, Cu, Al, TiN, TaN, polysilicon, silicide, or any combination thereof. In some implementations, at least one of the first electrode 178 or the second electrode 182 includes multiple conductive layers, such as a SiGe layer over a TiN layer. In some implementations, the dielectric structure 180 includes a dielectric material, such as silicon oxide, silicon nitride, or high-k dielectrics including, but not limited to, Al₂O₃, HfO₂, Ta₂O₅, ZrO₂, TiO₂, or any combination thereof.

As shown in FIG. 1D, the first electrode 178 includes a first portion 178a and a second portion 178b. The first portion 178a can extend through the isolating spacer layer 150 along the Z direction. The second portion 178b of the first electrode 178 extends from the first portion 178a along the first direction, e.g., the Z direction, away from the transistor 126 or the conductive structure 142. In some implementations, the second portions 178b of the first electrodes 178 of adjacent capacitors 128 are separated by at least one separation layer 184 along the second direction, e.g., Y direction. In some implementations, the separation layer 184 is made of a dielectric material including, but not limited to, polysilicon, carbon, or any combination thereof.

The width 154 of the first portion 178a along a second direction, e.g., the bit line direction or Y direction, is greater than an outer dimension 156 of the second portion 178b along the second direction, and greater than a width of the conductive structure 142 in contact with the first portion 178a. In some implementations, a separation distance 158 between first portions 178a of first electrodes 178 of adjacent capacitors 188 along Y direction is smaller than a separation distance 162 between second portions 178b of the first electrodes 178 of the adjacent capacitors 188. As noted above, because of the larger first portion 178a of the first electrode 178, the alignment between the capacitor 188 and the conductive structure 142 can be enhanced.

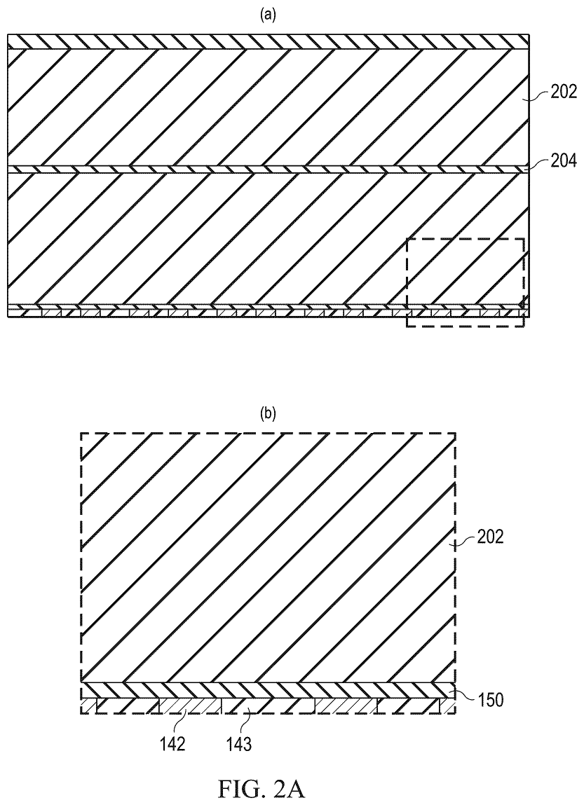

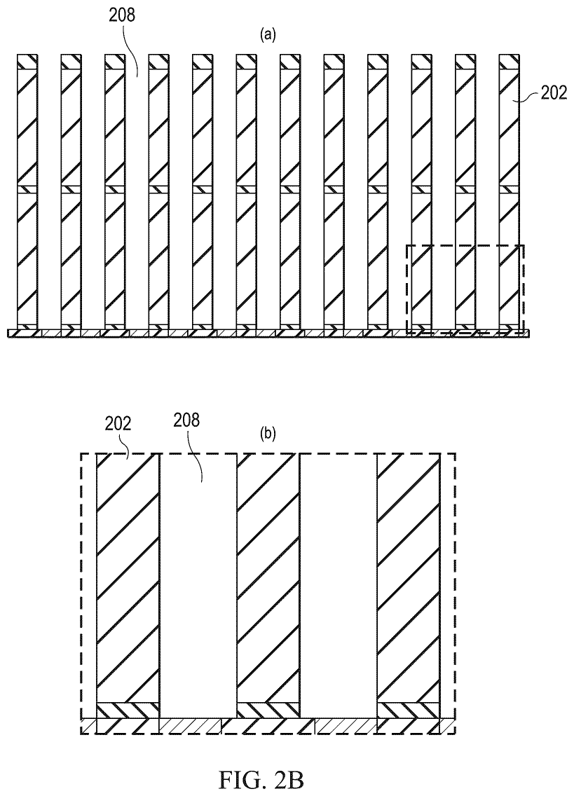

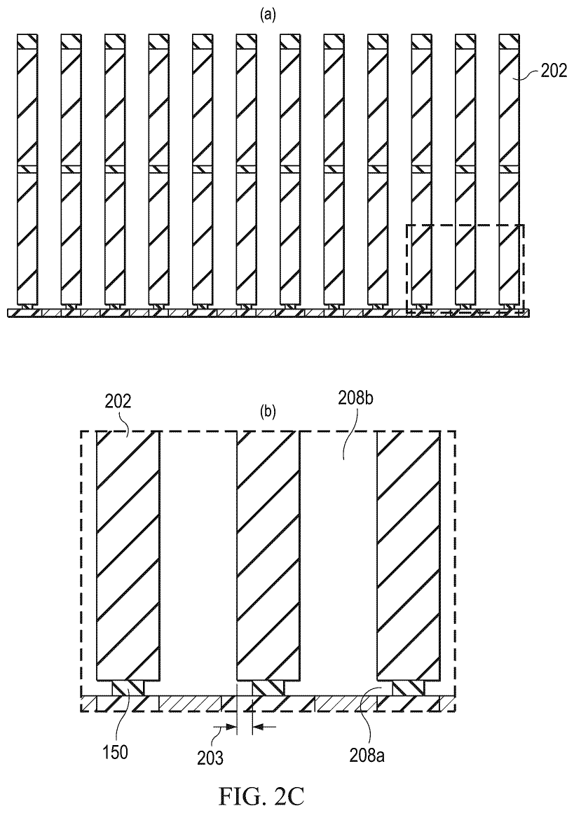

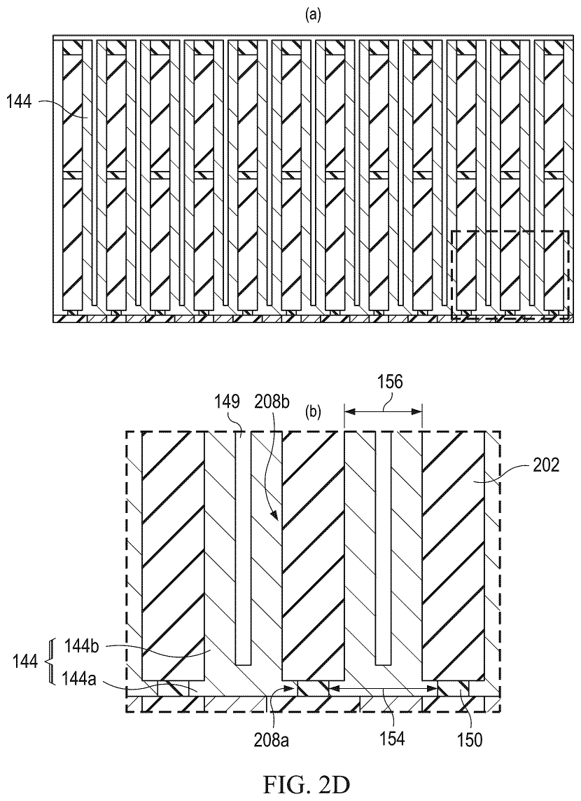

FIGS. 2A-2E illustrate cross-section views of an example semiconductor device 200 at various stages of an example fabrication process. The semiconductor device 200 can be implemented as the semiconductor device 100 or a part of the semiconductor device 100 of FIG. 1A. Each figure includes diagram (a) and diagram (b), where the diagram (b) is an enlarged view of a portion of the diagram (a) near the first portion 144a of the first electrode 144 of the capacitors 128. The example fabrication process is shown as being implemented with the capacitor 128 described with reference to FIGS. 1A-1C. However, this example fabrication process can be applicable with other suitable configurations of the capacitors.

Referring to FIGS. 1A and 2A, a conductive structure 142 can be formed on a first terminal 138a of the transistor 126 (e.g., as illustrated in FIG. 1A). Adjacent conductive structures 142 can be separated by a dielectric layer 143 that can include a dielectric material. The conductive structures 142 can be used to couple the transistors 126 and corresponding capacitors 128 and reduce a contact resistance. In some implementations, the conductive structure 142 includes at least one of metal or silicide, including without limitation to, W, Co, Cu, Al, NiSi, WSi, CoSi, CuSi, AlSi, or any other suitable metal silicides. In some implementations, the conductive structure 142 includes doped polysilicon. In some implementations, the conductive structure 142 includes multiple conductive layers, such as a silicide layer 142a over a polysilicon layer 142b.

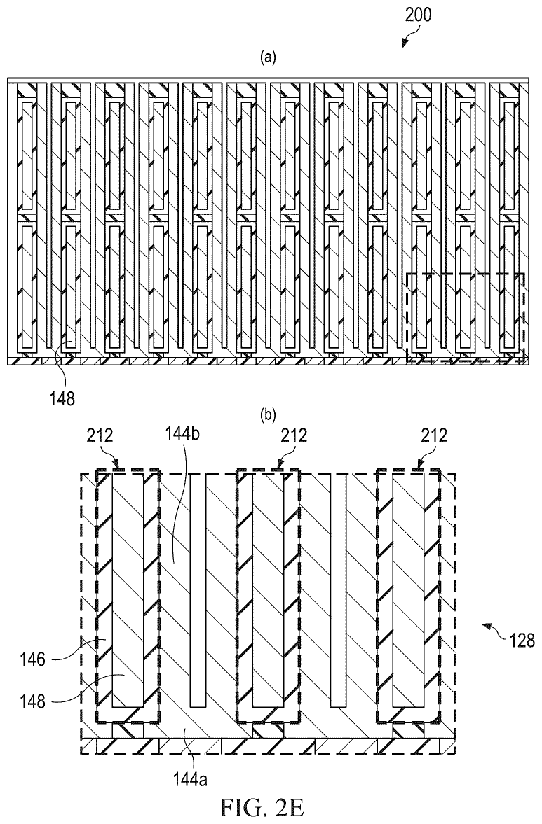

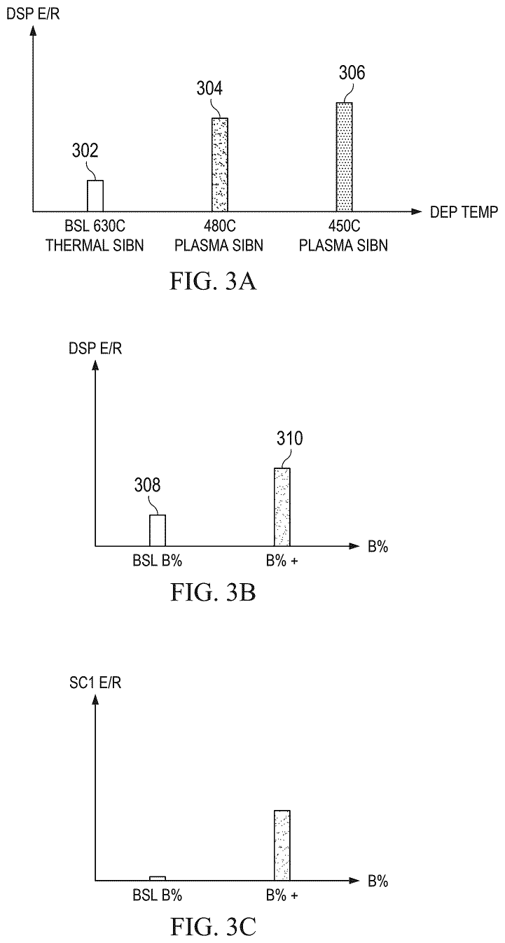

An isolating spacer layer 150 can be formed on the conductive structures 142 or the transistors 126. In some implementations, the isolating spacer layer 150 includes Silicon (Si), Boron (B), and Nitride (N). In some implementations, a concentration of Boron in the isolating spacer layer 150 is in a range from about 5% to about 70%. In some implementations, the isolating spacer layer 150 includes Silicon (Si), Carbon (C), and Nitride (N). The isolating spacer layer 150 can be deposited by one or more thin film deposition processes including, but not limited to, thermal CVD, PECVD, PVD, ALD, or any combination thereof. In some implementations, the isolating spacer layer 150 is deposited by plasma enhanced chemical vapor deposition (PECVD). In some implementations, forming the isolating spacer layer 150 includes controlling at least one of: a Boron (B) concentration, a ratio of a Silicon (Si) concentration to a Nitride (N) concentration, a plasma radio frequency (RF) power, or a deposition temperature in a deposition chamber. In some implementations, the deposition temperature is lower than about 600 degrees Celsius. As described with further details below in FIGS. 3A-3C, lower deposition temperature and/or higher Boron (B) concentration can lead to a higher etch rate on the isolating spacer layer 150 by wet etch.

A dielectric body 202 can be formed on the isolating spacer layer 150. In some implementations, the dielectric body 202 is made of a material including, but not limited to, silicon oxide, silicon nitride, silicon oxynitride, or any combination thereof. In some implementations, a supporting structure 204 is formed which extends through dielectric bodies 202 along X and/or Y direction. The supporting structure 204 can be used to support capacitors 128 that are formed at later stages of the process (e.g., FIG. 2E). In some implementations, the supporting structure 204 is made of dielectric materials, including, but not limited to, SiN, SiCN, or any combination thereof. The dielectric body 202 and the supporting structure 204 can be deposited using one or more thin film deposition techniques as described above.

As illustrated in FIG. 2B, a dry etch can be performed to form first openings 208 extending through the dielectric body 202 and the isolating spacer layer 150 along the first direction, e.g., Z direction. The etching process can involve dry etching techniques, including without limitation to, reactive icon etching (RIE), inductively coupled plasma (ICP) etching, deep reactive ion etching (DRIE), ion beam etching (IBE), plasma etching, or chemical vapor etching (CVE). The dry etching techniques can create high aspect ratio openings 208 as shown in diagram (a) of FIG. 2B.

As illustrated in FIG. 2C, the isolating spacer layer 150 can be partially etched by a first etchant in a wet etch. The first etchant can have a higher etch rate for the isolating spacer layer 150 than for the dielectric body 202. Therefore, the isolating spacer layer 150 can be removed more along X and Y directions compared to the dielectric body 202, creating undercuts under the dielectric body 202. The dimension of undercut is denoted by the undercut distance 203 in FIG. 2C. The first openings 208 can have two parts, e.g., a lower part 208a inside the isolating spacer layer 150 and an upper part 208b inside the dielectric body 202. The lower part 208a has a larger lateral dimension than that of the upper part 280a. In some implementations, the first etchant includes at least one of diluted sulfuric peroxide (DSP) or Standard Clean 1 (SC1).

As illustrated in FIG. 2D, the first electrode 144 can be formed by depositing a conductive material in the first openings 208. The first portion 144a of the first electrode 144 can be formed in a lower part 208a of the first opening 208, and the second portion 144b of the first electrode 144 can be formed in the upper part 208b of the first opening 208. The first portion 144a of the first electrode 144 of the capacitor 128 can be coupled to the first terminal 138a of the transistor 126 via the conductive structure 142 (e.g., as illustrated in FIG. 1A). As noted above, because of the undercut, the width 154 of the first portion 144a along a second direction, e.g., the bit line direction or Y direction, is greater than an outer dimension 156 of the second portion 144b. The conductive structure 142 can be within a region defined by the first portion 144a of the first electrode 144 of the capacitor 128 (e.g., as illustrated in FIG. 1C), providing better alignment.

The first electrode 144 can include a conductive material including, but not limited to W, Co, Cu, Al, TiN, TaN, polysilicon, silicide, or any combination thereof. In some implementations, the first electrode 144 includes multiple conductive layers, such as a W layer over a TiN layer. The first electrode 144 can be deposited by one or more thin film deposition processes including, but not limited to, Metal-Organic Chemical Vapor Deposition (MOCVD), sputtering, electroplating, electroless plating, electron-beam evaporation, or any combination thereof.

In some implementations, the filling structure 149 is formed inside the first opening 208. The filling structure 149 can be surrounded by the second portion 144b of the first electrode 144. In some implementations, the filling structure 149 is made of a dielectric material including, but not limited to, polysilicon, silicon carbide, or any combination thereof. The filling structure 149 can be deposited using one or more thin film deposition techniques, including, but not limited to, chemical vapor deposition (CVD), physical vapor deposition (PVD), atomic layer deposition (ALD), sputtering, or any combination thereof.

As illustrated in FIG. 2E, a second electrode 148 can be formed. Forming the second electrodes 148 can include multiple sub-steps. Although not depicted, the process sub-steps are described as follows.

In some implementations, the dielectric body 202 is removed by a second etchant in wet etch to form second openings 212 (e.g., regions enclosed by dashed line in diagram (b) of FIG. 2E). In contrast to that of the first etchant, the second etchant can have a lower etch rate for the isolating spacer layer 150 than for the dielectric body 202, such that it removes the dielectric body 202 while leaving the isolating spacer layer 150 largely intact. In some implementations, the second etchant includes hydrogen fluoride (HF). As the dielectric body 202 is removed at this stage, the sidewalls of the second portion 144b of the first electrode 144 can be exposed.

A dielectric structure 146 can be formed in the second openings 212, which is in contact with the sidewalls of the second portion 144b of the first electrode 144. The dielectric structure 146 can include materials, such as silicon oxide, silicon nitride, or high-k dielectrics including, but not limited to, Al₂O₃, HfO₂, Ta₂O₅, ZrO₂, TiO₂, or any combination thereof. The dielectric structure 146 can be deposited using one or more dielectric thin film deposition techniques, as described above.

The second electrode 148 can be subsequently formed on the dielectric structure 146 away from the first electrode 144 in the second openings 212, such that the dielectric structure 146 separates the first electrode 144 and the second electrode 148. The second electrode 148 and the dielectric structure 146 together can fill the second openings 212 as shown in FIG. 2E. The second electrode 148 can have identical or substantially similar material to that of the first electrode 144. In some implementations, at least one of the first electrode 144 or the second electrode 148 includes TiN.

FIGS. 3A-3C illustrate example relationships of etch rate on the isolating spacer layer 150 with respect to deposition temperatures, Boron (B) concentrations, and etchants. In the coordinate system of FIG. 3A, the horizontal axis represents the deposition temperature for isolating spacer layers, whereas the vertical axis represents the etch rate of the first etchant (e.g., DSP) on the isolating spacer layer 150. As noted above, the isolating spacer layer 150 can be formed by PECVD. PECVD may not require as high temperatures as thermal CVD techniques. Without being bound to any particular theory, in PECVD, the plasma energy can assist in breaking down the precursor gases, allowing deposition to occur at lower temperatures compared to thermal CVD. In FIG. 3A, the reference data point 302 represents the etch rate of the first etchant (e.g., DSP) on a reference isolating spacer layer (e.g., SiBN) formed by thermal CVD at 630 degrees Celsius. The data points 304, 306 represent the etch rates of DSP on the isolating spacer layer 150 (e.g., SiBN) formed by PECVD at 480 degrees Celsius and 450 degrees Celsius, respectively. As illustrated, compared to thermal CVD, the isolating spacer layers 150 formed by PECVD at lower temperatures can be more susceptible to DSP etch. In other words, DSP has a higher etch rate (e.g., about 3 times higher) on the isolating spacer layer 150 formed with PECVD. In addition, lowering deposition temperature can further increase etch rate (e.g., comparing data point 304 and 306), for example, 4 times higher than the data point 302.

In the coordinate system of FIG. 3B, the horizontal axis represents the Boron concentration of isolating spacer layers, whereas the vertical axis represents the etch rate of the first etchant (e.g., DSP). The data point 308 represents the DSP etch rate on a reference isolating spacer layer with a lower concentration of B, while the data point 310 corresponds to the isolating spacer layer 150 with a higher B concentration. As shown, higher B concentration can result in higher DSP etch rate on the isolating spacer layers 150. Similarly, FIG. 3C illustrates that, for another type of first etchant (e.g., SC1) a higher B concentration can lead to a higher SC1 etch rate on the isolating spacer layers 150.

Referring back to FIG. 2C, a higher etch rate on the isolating spacer layer 150 can lead to a greater undercut distance 203, which, in turn, provides a larger first portion 144a of the first electrode 144 of the capacitors 128. Larger first portion 144a of the first electrode 144 can enhance alignment with the conductive structures 142 or the transistors 126.

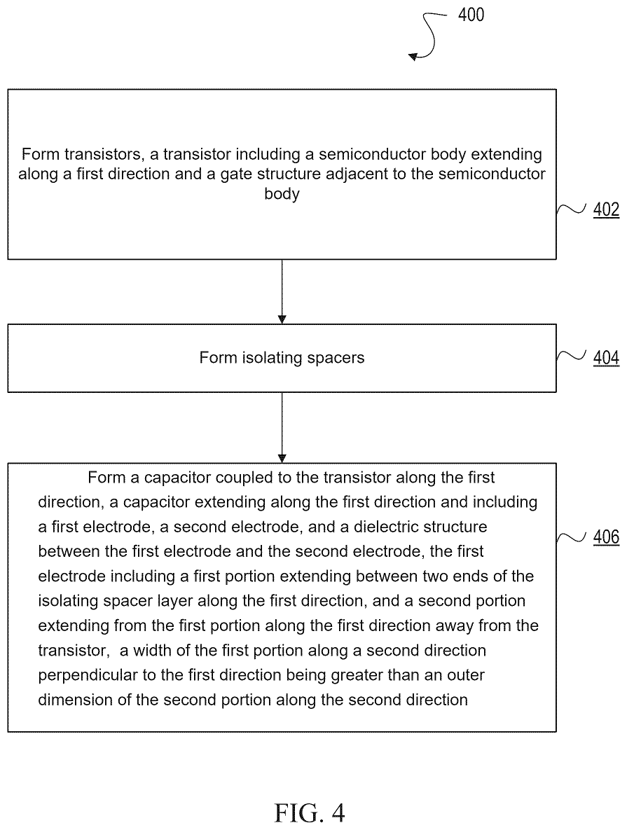

FIG. 4 is a flow diagram of an example process 400 for forming a semiconductor device. The semiconductor device can be, e.g., the semiconductor device 100 of FIG. 1A, or a part of the semiconductor device 100 of FIGS. 1B and 1D, or the semiconductor device 200 of FIG. 2E.

At step 402, a transistor is formed. The transistor includes a semiconductor body extending along a first direction and a gate structure adjacent to the semiconductor body. The transistor can be, e.g., the transistor 126 of FIGS. 1A-1B. The semiconductor body can be, e.g., the semiconductor body 130 of FIGS. 1A-1B. The gate structure can be, e.g., the gate structure 136 of FIG. 1A. The first direction can be, e.g., the Z direction in FIGS. 1A-1B and 1D-2E.

At step 404, an isolating spacer layer is formed. The isolating spacer layer can be, e.g., the isolating spacer layer 150 of FIGS. 1A-1B and 1D-2E.

At step 406, a capacitor is coupled to the transistor along the first direction. A capacitor extends along the first direction and includes a first electrode, a second electrode, and a dielectric structure between the first electrode and the second electrode. The first electrode includes a first portion extending between two ends of the isolating spacer layer along the first direction, and a second portion extending from the first portion along the first direction away from the transistor. A width of the first portion along a second direction perpendicular to the first direction is greater than an outer dimension of the second portion along the second direction. The capacitor can be, e.g., the capacitor 128 of FIGS. 1A-1B and 2E, or the capacitor 188 of FIG. 1D. The first electrode can be, e.g., the first electrode 144 of FIGS. 1A-1B and 2D-2E, or the first electrode 178 of FIG. 1D. The second electrode can be, e.g., the second electrode 148 of FIGS. 1A-1B and 2E, or the second electrode 182 of FIG. 1D. The first portion of the first electrode can be, e.g., the first portion 144a of the first electrode 144 of FIGS. 1A-1B and 2D-2E, or the first portion 178a of the first electrode 178 of FIG. 1D. The second portion of the first electrode can be, e.g., the second portion 144b of the first electrode 144 of FIGS. 1A-1B and 2E, or the second portion 178b of the first electrode 178 of FIG. 1D. The width of the first portion can be, e.g., the width 154 of the first portion 144a of FIGS. 1B-1C and 2D, or the width 154 of the first portion 178a of FIG. 1D. The outer dimension of the second portion can be, e.g., the outer dimension 156 of the second portion 144b of FIGS. 1B-1C and 2D, or the outer dimension 156 of the second portion 178b of FIGS. 1B-1C and 2D.

In some implementations, a dielectric body is formed on the isolating spacer layer. The first openings are formed which extend through the dielectric body and the isolating spacer layer along the first direction. The isolating spacer layer is partially etched by a first etchant. The first etchant has a higher etch rate for the isolating spacer layer than for the dielectric body. The dielectric body can be, e.g., the dielectric body 202 of FIGS. 2A-2D. The first openings can be, e.g., the first openings 208 of FIGS. 2B-2C. In some implementations, the first etchant includes at least one of diluted sulfuric peroxide (DSP) or Standard Clean 1 (SC1) etchant.

In some implementations, the dielectric body is removed by a second etchant to form second openings. The second etchant has a lower etch rate for the isolating spacer layer than for the dielectric body. The second openings can be, e.g., the second openings 212 of FIG. 2E. In some implementations, the second etchant comprises hydrogen fluoride (HF).

In some implementations, forming the capacitor includes: forming, in the first openings, the first electrode; forming, in the second openings, the dielectric structure in contact with the first electrode; and forming, in the second openings, the second electrode on the dielectric structure away from the first electrode. In some implementations, at least one of a material of the first electrode or a material of the second electrode includes TiN.

In some implementations, forming the first openings includes etching the dielectric body and the isolating spacer layer by dry etching.

In some implementations, forming the isolating spacer layer includes depositing an isolating material by plasma enhanced chemical vapor deposition (PECVD). In some implementations, the isolating material includes Silicon (Si), Nitride (N), and Boron (B). In some implementations, the isolating material includes Silicon (Si), Nitride (N), and Carbon (C).

In some implementations, forming the isolating spacer layer includes controlling at least one of: a Boron (B) concentration, a ratio of a Silicon (Si) concentration to a Nitride (N) concentration, a plasma radio frequency (RF) power, or a deposition temperature in a deposition chamber. In some implementations, the deposition temperature is lower than about 600 degrees Celsius.

In some implementations, a conductive structure is formed on a first terminal of the transistor. The first portion of the first electrode of the capacitor is coupled to the first terminal of the transistor via the conductive structure.

In some implementations, the first portion of the first electrode of the capacitor has a larger area in a plane perpendicular to the first direction than an area of the conductive structure. The conductive structure is within a region defined by the first portion of the first electrode of the capacitor. The region can be, e.g., the region 172 of FIG. 1C.

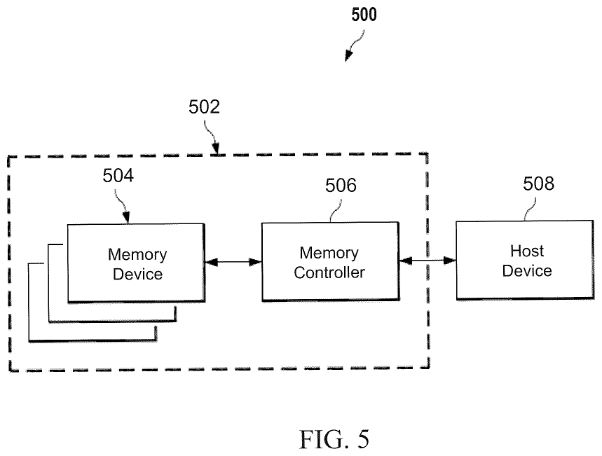

FIG. 5 illustrates a block diagram of a system 500 having one or more semiconductor devices (e.g., memory devices), according to one or more implementations of the present disclosure. The system 500 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 5, the system 500 can include a host device 508 and a memory system 502 having one or more 3D memory devices 504 and a memory controller 506. Host device 508 can include a processor of an electronic device, such as a central processing unit (CPU), or a system-on-chip (SoC), such as an application processor (AP). Host device 508 can be configured to send or receive data to or from the one or more 3D memory devices 504.

A 3D memory device 504 can be any 3D memory device disclosed herein, such as the 3D semiconductor device 100 of FIG. 1A, or a part of the 3D semiconductor device 100 of FIGS. 1B and 1D, or a structure at an intermediate fabrication process of the 3D semiconductor device 100 or the semiconductor device 200 of FIGS. 2A-2E.

In some implementations, a 3D memory device 504 includes a NAND Flash memory.

Memory controller 506 (a.k.a., a controller circuit) is coupled to 3D memory device 504 and host device 508. Consistent with implementations of the present disclosure, 3D memory device 504 can include a plurality of conductive interconnections through a cover layer that are in contact with conductive pads in a conductive pad layer, and memory controller 506 can be coupled to 3D memory device 504 through at least one of the plurality of conductive interconnections. Memory controller 506 is configured to control 3D memory device 504. For example, memory controller 506 may be configured to operate a plurality of channel structures via word lines. Memory controller 506 can manage data stored in 3D memory device 504 and communicate with host device 508.

In some implementations, memory controller 506 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 506 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 506 can be configured to control operations of 3D memory device 504, such as read, erase, and program (or write) operations. Memory controller 506 can also be configured to manage various functions with respect to the data stored or to be stored in 3D memory device 504 including, but not limited to bad-block management, garbage collection, logical-to-physical address conversion, wear leveling, etc. In some implementations, memory controller 506 is further configured to process error correction codes (ECCs) with respect to the data read from or written to 3D memory device 504. Any other suitable functions may be performed by memory controller 506 as well, for example, formatting 3D memory device 504.

Memory controller 506 can communicate with an external device (e.g., host device 508) according to a particular communication protocol. For example, memory controller 506 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 506 and one or more 3D memory devices 504 can be integrated into various types of storage devices, for example, be included in the same package, such as a universal Flash storage (UFS) package or an eMMC package. That is, memory system 502 can be implemented and packaged into different types of end electronic products. In one example as shown in FIG. 5, memory controller 506 and a single 3D memory device 504 may be integrated into a memory card 502. Memory card 502 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some embodiments,” “some implementations,” “one implementation,” “an implementation,” “an example implementation,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for case of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors 126 (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
a transistor comprising a semiconductor body extending along a first direction and a gate structure adjacent to the semiconductor body;
a capacitor coupled to the transistor along the first direction, wherein the capacitor extends along the first direction and comprises a first electrode, a second electrode, and a dielectric structure between the first electrode and the second electrode; and
an isolating spacer layer between the transistor and the capacitor along the first direction,
wherein the first electrode comprises a first portion extending between two ends of the isolating spacer layer along the first direction, and a second portion extending from the first portion along the first direction away from the transistor, and
wherein a width of the first portion along a second direction perpendicular to the first direction is greater than an outer dimension of the second portion along the second direction.

2. The semiconductor device of claim 1, comprising a plurality of capacitors including the capacitor, wherein a separation distance between first portions of first electrodes of adjacent capacitors along the second direction is smaller than a separation distance between second portions of the first electrodes of the adjacent capacitors along the second direction.

3. The semiconductor device of claim 1, wherein the first portion of the first electrode of the capacitor is coupled to a first terminal of a corresponding transistor via a conductive structure.

4. The semiconductor device of claim 3, wherein the first portion of the first electrode of the capacitor has a larger area in a plane perpendicular to the first direction than an area of the conductive structure in the plane.

5. The semiconductor device of claim 4, wherein the conductive structure is within a region defined by the first portion of the first electrode of the capacitor.

6. The semiconductor device of claim 1, wherein the isolating spacer layer comprises Silicon (Si), Boron (B), and Nitride (N).

7. The semiconductor device of claim 6, wherein a concentration of Boron in the isolating spacer layer is in a range from about 5% to about 70%.

8. The semiconductor device of claim 1, wherein the isolating spacer layer comprises Silicon (Si), Carbon (C), and Nitride (N).

9. The semiconductor device of claim 1, wherein the capacitor comprises a filling structure extending along the first direction, and the first electrode is in contact with at least one surface of the filling structure.

10. A method of forming a semiconductor device, the method comprising:
forming a transistor comprising a semiconductor body extending along a first direction and a gate structure adjacent to the semiconductor body;
forming an isolating spacer layer; and
forming a capacitor coupled to the transistor along the first direction, wherein the capacitor extends along the first direction and comprises a first electrode, a second electrode, and a dielectric structure between the first electrode and the second electrode,
wherein the first electrode comprises a first portion extending between two ends of the isolating spacer layer along the first direction, and a second portion extending from the first portion along the first direction away from the transistor, and
wherein a width of the first portion along a second direction perpendicular to the first direction is greater than an outer dimension of the second portion along the second direction.

11. The method of claim 10, comprising:
forming a dielectric body on the isolating spacer layer;
forming first openings extending through the dielectric body and the isolating spacer layer along the first direction; and
partially etching the isolating spacer layer by a first etchant, wherein the first etchant has a higher etch rate for the isolating spacer layer than for the dielectric body.

12. The method of claim 11, wherein the first etchant comprises at least one of diluted sulfuric peroxide (DSP) or Standard Clean 1 (SC1) etchant.

13. The method of claim 11, comprising:
removing the dielectric body by a second etchant to form second openings, wherein the second etchant has a lower etch rate for the isolating spacer layer than for the dielectric body.

14. The method of claim 13, wherein forming the capacitor comprises:
forming, in the first openings, the first electrode;
forming, in the second openings, the dielectric structure in contact with the first electrode; and
forming, in the second openings, the second electrode on the dielectric structure away from the first electrode.

15. The method of claim 11, wherein forming the first openings comprises:
etching the dielectric body and the isolating spacer layer by dry etching.

16. The method of claim 10, wherein forming the isolating spacer layer comprises:
depositing an isolating material by plasma enhanced chemical vapor deposition (PECVD).

17. The method of claim 16, wherein the isolating material comprises Silicon (Si), Nitride (N), and Boron (B).

18. The method of claim 16, wherein forming the isolating spacer layer comprises controlling at least one of:
a Boron (B) concentration,
a ratio of a Silicon (Si) concentration to a Nitride (N) concentration,
a plasma radio frequency (RF) power, or
a deposition temperature in a deposition chamber.

19. The method of claim 11, further comprising:
forming a conductive structure on a first terminal of the transistor,
wherein the first portion of the first electrode of the capacitor is coupled to the first terminal of the transistor via the conductive structure.

20. A system, comprising:
a memory device configured to store data, the memory device comprising:
a transistor comprising a semiconductor body extending along a first direction and a gate structure adjacent to the semiconductor body,
a capacitor coupled to the transistor along the first direction, wherein the capacitor extends along the first direction and comprises a first electrode, a second electrode, and a dielectric structure between the first electrode and the second electrode, and
an isolating spacer layer between the transistor and the capacitor along the first direction,
wherein the first electrode comprises a first portion extending between two ends of the isolating spacer layer along the first direction, and a second portion extending from the first portion along the first direction away from the transistor, and
wherein a width of the first portion along a second direction perpendicular to the first direction is greater than an outer dimension of the second portion along the second direction; and
a memory controller coupled to the memory device and configured to operate the memory device.
